(19) United States
(12) Patent Application Publication
(10) Pub. No.: US 2024/0304472 A1
(43) Pub. Date: Sep. 12, 2024

(54) LIGHT IRRADIATION TYPE HEAT TREATMENT APPARATUS AND HEAT TREATMENT METHOD

(71) Applicant: SCREEN Holdings Co., Ltd., Kyoto (JP)

(72) Inventor: Tomohiro UENO, Kyoto-shi (JP)

(21) Appl. No.: 18/394,709

(22) Filed: Dec. 22, 2023

(30) Foreign Application Priority Data
Mar. 7, 2023 (JP) 2023-034160

(51) Int. Cl. H01L 21/67; H01L 21/66; H01L 21/677

(52) U.S. Cl. CPC H01L 21/67115; H01L 21/67706; H01L 21/67745; H01L 21/67766; H01L 22/12

(57) ABSTRACT

Preheating is performed on a semiconductor wafer by irradiation with light from halogen lamps in a treatment chamber, and heating treatment is thereafter performed on the semiconductor wafer by irradiation with a flash of light from flash lamps. A controller transmits an advance notice signal to a planning part at a time that is a certain amount of time before the time at which the heating treatment of the semiconductor wafer is completed in the treatment chamber. The planning part executes replanning of transport so that the transport operation being performed by a transport robot when receiving the advance notice signal is followed by the transport of the semiconductor wafer from the treatment chamber. The planning part executes the replanning of the transport each time the heating treatment of a semiconductor wafer is performed. Thus, the transport of the semiconductor wafer is adjusted automatically and rapidly.

### BACKGROUND OF THE INVENTION

### Field of the Invention

The present invention relates to a heat treatment apparatus and a heat treatment method which irradiate a substrate received in a treatment chamber with light from lamps to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

U.S. Patent Application Publication No. 2020/0243357 discloses a heat treatment apparatus which irradiates a semiconductor wafer received in a treatment chamber with light from halogen lamps to preheat the semiconductor wafer, and thereafter irradiates a front surface of the semiconductor wafer with flashes of light. It is also disclosed in U.S. Patent Application Publication No. 2020/0243357 that one hand of a transport robot is used to take a preceding semiconductor wafer subjected to heating treatment out of the treatment chamber, and the other hand of the transport robot is used to transport an untreated semiconductor wafer into the treatment chamber, whereby wafer exchange is performed.

In a heat treatment apparatus, it is desirable to achieve a situation in which a semiconductor wafer is constantly present in a treatment chamber by performing the wafer exchange for the purpose of maintaining a uniform temperature state in the treatment chamber. To ensure the wafer exchange, it is necessary that, when the treatment of a preceding semiconductor wafer is completed, a transport robot holds a succeeding semiconductor wafer and waits in front of the treatment chamber. To this end, the treatment time of a recipe has been conventionally manually adjusted so that the treatment in the treatment chamber is the rate-determining step in a procedure for a series of processes of semiconductor wafers. In other words, the adjustment has been made so that the treatment time in the treatment chamber is longer than the time required for the semiconductor wafer taken out of a carrier (or cassette) to be transported to the treatment chamber. Specifically, for example, the time for an alignment process prior to heating treatment has been shortened, or the waiting time after flash irradiation in the treatment chamber has been prolonged. This ensures the wafer exchange, and as a result causes a semiconductor wafer to be constantly present in the chamber, thereby stabilizing the temperature in the chamber.

However, the manual adjustment, which has been made based on the actually measured processing time for various processes including the heating treatment, has required a long period of time because the processing time is not stable depending on the environment. It is hence required to automatically and rapidly adjust the transport of semiconductor wafers.

There has been another problem that the actual time required for the heating treatment in the treatment chamber varies in some cases even if the processing time is adjusted in the recipe. This is due to the fact that the feedback control of halogen lamps is performed for the preheating of a semiconductor wafer, based on the measured values of a radiation thermometer, and that accurate temperature control cannot be performed if the measurement of the radiation thermometer is affected by disturbance light resulting from the state of the treatment chamber. If the time for the heating treatment in the treatment chamber is short, the succeeding semiconductor wafer is not ready to be transported into the treatment chamber in some cases when the treatment of the preceding semiconductor wafer in the treatment chamber is completed. This results in cases in which the wafer exchange cannot be performed.

If the wafer exchange cannot be performed, the preceding semiconductor wafer will remain in the high-temperature treatment chamber for a longer period of time than necessary after the completion of the heating treatment, which might affect the treatment result of the preceding semiconductor wafer. For example, impurities implanted in the semiconductor wafer might diffuse deeper than necessary as a result of a greater amount of heat than necessary added to the semiconductor wafer.

Also, if only the preceding semiconductor wafer is transported out of the treatment chamber without performing the wafer exchange, there will arise a time period during which no semiconductor wafer is present in the treatment chamber. When no semiconductor wafer is present in the treatment chamber, heating is not performed by the halogen lamps and flash lamps. The longer the time period during which no semiconductor wafer is present in the treatment chamber is, the lower the temperature of the treatment chamber becomes. This causes different temperatures of the treatment chamber for multiple semiconductor wafers constituting a lot, which in turn results in non-uniform treatment results among the multiple semiconductor wafers.

### SUMMARY

The present invention is intended for a heat treatment apparatus for heating a substrate by irradiating the substrate with light.

According to one aspect of the present invention, the heat treatment apparatus comprises: a treatment chamber for receiving a substrate therein; a lamp for irradiating the substrate received in the treatment chamber with light; a plurality of attendant processing parts for performing processes before and after heating treatment in the treatment chamber; a transport robot for transporting the substrate to and from the treatment chamber and the attendant processing parts; a controller for controlling a mechanism provided in the heat treatment apparatus; a planning part for creating a transport plan based on previously registered processing time in the treatment chamber and in the attendant processing parts; and an execution instruction part for instructing the controller to execute the transport and processes of substrates in accordance with the transport plan created by the planning part.

The transport of the substrate is adjusted rapidly.

Preferably, the controller transmits an advance notice signal to the planning part at a time that is a certain amount of time before the time at which the heating treatment is completed in the treatment chamber; and when receiving the advance notice signal from the controller, the planning part executes replanning of transport so that the transport robot is able to transport the substrate from the treatment chamber at the time of completion of the heating treatment in the treatment chamber.

The substrate subjected to the heating treatment is transported from the treatment chamber without waiting in the treatment chamber.

Preferably, the planning part creates a transport plan so that priority is placed on the transport of a substrate not yet subjected to the heating treatment when the transport of the substrate not yet subjected to the heating treatment and the transport of a substrate subjected to the heating treatment by the transport robot compete with each other.

When the heating treatment of the preceding substrate is completed, the succeeding substrate has reached the transport robot. This ensures the substrate exchange in the treatment chamber.

The present invention is also intended for a method of heating a substrate received in a treatment chamber by irradiating the substrate with light from a lamp.

According to one aspect of the present invention, the method comprises the steps of: (a) transporting substrates to and from the treatment chamber and a plurality of attendant processing parts for performing processes before and after heating treatment in the treatment chamber by means of a transport robot under the control of a controller; (b) creating a transport plan by means of a planning part, based on previously registered processing time in the treatment chamber and in the attendant processing parts; and (c) instructing the controller to execute the transport and processes of the substrates in accordance with the transport plan created in the step (b).

The transport of the substrate is adjusted rapidly.

Preferably, the controller transmits an advance notice signal to the planning part at a time that is a certain amount of time before the time at which the heating treatment is completed in the treatment chamber; and when receiving the advance notice signal from the controller, the planning part executes replanning of transport so that the transport robot is able to transport a substrate from the treatment chamber at the time of completion of the heating treatment in the treatment chamber.

The substrate subjected to the heating treatment is transported from the treatment chamber without waiting in the treatment chamber.

Preferably, a transport plan is created in the step (b) so that priority is placed on the transport of a substrate not yet subjected to the heating treatment when the transport of the substrate not yet subjected to the heating treatment and the transport of a substrate subjected to the heating treatment by the transport robot compete with each other.

When the heating treatment of the preceding substrate is completed, the succeeding substrate has reached the transport robot. This ensures the substrate exchange in the treatment chamber.

It is therefore a primary object of the present invention to adjust the transport of a substrate rapidly.

It is another object of the present invention to transport a substrate subjected to heating treatment from a treatment chamber without waiting in the treatment chamber.

It is still another object of the present invention to ensure substrate exchange in the treatment chamber.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a heat treatment apparatus according to the present invention;

FIG. 2 is a longitudinal sectional view showing a configuration of a heat treatment part;

FIG. 3 is a perspective view showing the entire external appearance of a holder;

FIG. 4 is a plan view of a susceptor;

FIG. 5 is a sectional view of the susceptor;

FIG. 6 is a plan view of a transfer mechanism;

FIG. 7 is a side view of the transfer mechanism;

FIG. 8 is a plan view showing an arrangement of halogen lamps;

FIG. 9 is a block diagram showing a configuration of a controller, a planning part, and an execution instruction part;

FIG. 10 is a flow diagram showing a procedure for transport control of semiconductor wafers in a first preferred embodiment;

FIG. 11 is a graph showing changes in temperature of a semiconductor wafer during heating treatment in a heat treatment part; and

FIG. 12 is a schematic illustration of priority transport of a semiconductor wafer in an outward path.

### DESCRIPTION OF THE PREFERRED EMBODIMENTS

Preferred embodiments according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

### First Preferred Embodiment

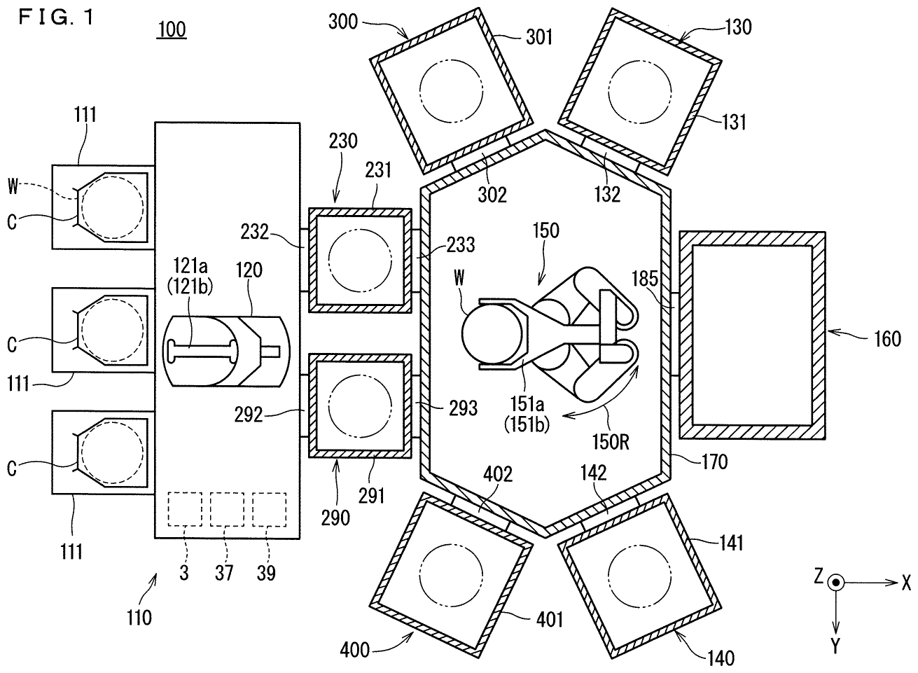

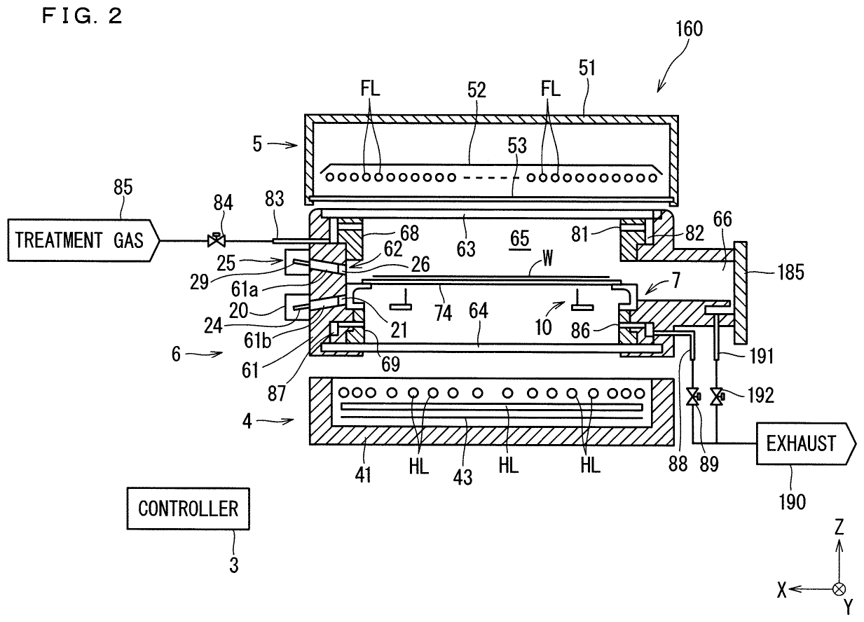

FIG. 1 is a plan view of a heat treatment apparatus 100 according to the present invention. The heat treatment apparatus 100 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding. An XYZ rectangular coordinate system in which an XY plane is defined as a horizontal plane and a Z axis is defined to extend in a vertical direction is additionally shown in FIGS. 1 and 2 for purposes of clarifying the directional relationship therebetween.

The heat treatment apparatus 100 includes: an indexer part 110 for transporting untreated semiconductor wafers W from the outside into the heat treatment apparatus 100 and for transporting treated semiconductor wafers W to the outside of the heat treatment apparatus 100; an alignment part 230 for positioning an untreated semiconductor wafer W; a warpage measurement part 290 for measuring the warpage of a semiconductor wafer W; two cooling parts 130 and 140 each for cooling a semiconductor wafer W subjected to heating treatment; a flaw detection part 300 for detecting the presence or absence of flaws in a back surface of a semiconductor wafer W; a film thickness measurement part 400 for measuring the thickness of a thin film formed on a semiconductor wafer W; and a heat treatment part 160 for performing flash heating treatment on a semiconductor wafer W. The heat treatment apparatus 100 further includes a transport robot 150 for transferring a semiconductor wafer W to and from the cooling parts 130 and 140, the flaw detection part 300, the film thickness measurement part 400, and the heat treatment part 160. The heat treatment apparatus 100 further includes: a controller 3 for controlling operating mechanisms provided in the aforementioned processing parts and the transport robot 150 to cause the flash heating treatment of the semiconductor wafer W to proceed; a planning part 37 for creating a transport plan for semiconductor wafers W in the heat treatment apparatus 100; and an execution instruction part 39 for providing instructions in accordance with the transport plan to the controller 3.

The indexer part 110 is disposed in an end portion of the heat treatment apparatus 100. The indexer part 110 includes three load ports 111 and a transfer robot 120. The three load ports 111 are arranged in juxtaposition along the Y axis in the end portion of the heat treatment apparatus 100. Each of the load ports 111 is capable of placing a single carrier (or cassette) C thereon. Accordingly, a maximum of three carriers C are placed on the indexer part 110. An unmanned transport vehicle (an AGV (automatic guided vehicle) or an OHT (overhead hoist transfer)) or the like transports a carrier C with untreated semiconductor wafers W stored therein to place the carrier C on the load ports 111. The unmanned transport vehicle also carries a carrier C with treated semiconductor wafers W stored therein away from the load ports 111. A dummy carrier with dummy wafers stored therein may be placed on one of the three load ports 111.

In the load ports 111, the carriers C are movable upwardly and downwardly so that the transfer robot 120 is able to load any semiconductor wafer W into each of the carriers C and unload any semiconductor wafer W from each of the carriers C. The carriers C may be of the following types: an SMIF (standard mechanical interface) pod and an OC (open cassette) which exposes stored semiconductor wafer W to the outside atmosphere, in addition to a FOUP (front opening unified pod) which stores semiconductor wafer W in an enclosed or sealed space.

The transfer robot 120 is configured to be slidable along the Y axis, pivotable about the Z axis, and movable upwardly and downwardly along the Z axis. The transfer robot 120 includes two transfer hands 121a and 121b each capable of holding a semiconductor wafer W. The transfer hands 121a and 121b are vertically spaced a predetermined distance apart from each other, and are independently linearly movable forwardly and backwardly in the same horizontal direction. Thus, the transfer robot 120 loads and unloads semiconductor wafers W into and from the carriers C placed on any load port 111, and transfers semiconductor wafers W to and from the alignment part 230 and the warpage measurement part 290. The operation of the transfer robot 120 loading and unloading the semiconductor wafers W into and from the carriers C is achieved by the forward and backward movement of the transfer hand 121a (or the transfer hand 121b) and the upward and downward movement of the carriers C. The transfer of the semiconductor wafers W between the transfer robot 120 and the alignment part 230 or between the transfer robot 120 and the warpage measurement part 290 is achieved by the forward and backward movement of the transfer hand 121a (or the transfer hand 121b) and the upward and downward movement of the transfer robot 120.

The alignment part 230 and the warpage measurement part 290 are provided between the indexer part 110 and a transport chamber 170 so as to connect the indexer part 110 and the transport chamber 170. The alignment part 230 is a processing part for rotating a semiconductor wafer W in a horizontal plane to an orientation appropriate for flash heating. The alignment part 230 includes an alignment chamber 231 which is a housing made of an aluminum alloy, a mechanism provided in the alignment chamber 231 and for supporting and rotating a semiconductor wafer W in a horizontal attitude, a mechanism provided in the alignment chamber 231 and for optically detecting a notch, an orientation flat, and the like formed in a peripheral portion of a semiconductor wafer W, and the like.

A gate valve 232 is provided in a connector portion between the alignment chamber 231 and the indexer part 110. An opening for communication between the alignment chamber 231 and the indexer part 110 is openable and closable by the gate valve 232. A gate valve 233 is provided in a connector portion between the alignment chamber 231 and the transport chamber 170. An opening for communication between the alignment chamber 231 and the transport chamber 170 is openable and closable by the gate valve 233. In other words, the alignment chamber 231 and the indexer part 110 are connected to each other via the gate valve 232, and the alignment chamber 231 and the transport chamber 170 are connected to each other via the gate valve 233.

The gate valve 232 is opened when a semiconductor wafer W is transferred between the indexer part 110 and the alignment chamber 231. The gate valve 233 is opened when a semiconductor wafer W is transferred between the alignment chamber 231 and the transport chamber 170. When the gate valve 232 and the gate valve 233 are closed, the interior of the alignment chamber 231 is an enclosed space.

The alignment part 230 rotates the semiconductor wafer W received from the transfer robot 120 of the indexer part 110 about a vertical axis passing through the central portion of the semiconductor wafer W to optically detect a notch and the like, thereby adjusting the orientation of the semiconductor wafer W. The semiconductor wafer W subjected to the orientation adjustment is taken out of the alignment part 230 by the transport robot 150.

The warpage measurement part 290 is a processing part for measuring the warpage of a semiconductor wafer W subjected to the heating treatment. The warpage measurement part 290 includes a warpage measurement chamber 291 which is a housing made of an aluminum alloy, a mechanism provided in the warpage measurement chamber 291 and for holding a semiconductor wafer W, a mechanism provided in the warpage measurement chamber 291 and for optically detecting the warpage of a semiconductor wafer W, and the like.

A gate valve 292 is provided in a connector portion between the warpage measurement chamber 291 and the indexer part 110. An opening for communication between the warpage measurement chamber 291 and the indexer part 110 is openable and closable by the gate valve 292. A gate valve 293 is provided in a connector portion between the warpage measurement chamber 291 and the transport chamber 170. An opening for communication between the warpage measurement chamber 291 and the transport chamber 170 is openable and closable by the gate valve 293. In other words, the warpage measurement chamber 291 and the indexer part 110 are connected to each other via the gate valve 292, and the warpage measurement chamber 291 and the transport chamber 170 are connected to each other via the gate valve 293.

The gate valve 292 is opened when a semiconductor wafer W is transferred between the indexer part 110 and the warpage measurement chamber 291. The gate valve 293 is opened when a semiconductor wafer W is transferred between the warpage measurement chamber 291 and the transport chamber 170. When the gate valve 292 and the gate valve 293 are closed, the interior of the warpage measurement chamber 291 is an enclosed space.

The warpage measurement part 290 optically measures the wafer warpage occurring in the semiconductor wafer W subjected to the heating treatment and received from the transport robot 150. After the warpage measurement is completed, the semiconductor wafer W is taken out of the warpage measurement part 290 by the transfer robot 120 of the indexer part 110.

The transport robot 150 is housed in the transport chamber 170. The alignment chamber 231, the warpage measurement chamber 291, a cool chamber 131 in the cooling part 130, a cool chamber 141 in the cooling part 140, a flaw detection chamber 301 in the flaw detection part 300, a film thickness measurement chamber 401 in the film thickness measurement part 400, and a treatment chamber 6 in the heat treatment part 160 are connected around the transport chamber 170.

The transport robot 150 provided in the transport chamber 170 is pivotable about a vertical axis (Z axis) as indicated by an arrow 150R. The transport robot 150 includes two linkage mechanisms comprised of a plurality of arm segments. Transport hands 151a and 151b each for holding a semiconductor wafer W are provided at respective distal ends of the two linkage mechanisms. These transport hands 151a and 151b are vertically spaced a predetermined distance apart from each other, and are independently linearly slidable in the same horizontal direction by the respective linkage mechanisms. The transport robot 150 moves a base provided with the two linkage mechanisms upwardly and downwardly to thereby move the two transport hands 151a and 151b spaced the predetermined distance apart from each other upwardly and downwardly.

When the transport robot 150 transfers (loads and unloads) a semiconductor wafer W to and from the alignment chamber 231, the warpage measurement chamber 291, the cool chamber 131, the cool chamber 141, the flaw detection chamber 301, the film thickness measurement chamber 401, or the treatment chamber 6 in the heat treatment part 160 as a transfer target, both of the transport hands 151a and 151b initially pivot into opposed relation to the transfer target. Thereafter (or during the pivotal movement), the transport robot 150 moves the transport hands 151a and 151b upwardly or downwardly to position one of the transport hands 151a and 151b at the same height as the opening of the transfer target. Then, the transport robot 150 causes the transport hand 151a (or 151b) to linearly slide in a horizontal direction, thereby transferring the semiconductor wafer W to and from the transfer target.

The heat treatment part 160 which is a principal part of the heat treatment apparatus 100 is a substrate processing part for irradiating a preheated semiconductor wafer W with flashes of light from xenon flash lamps FL to perform flash heating treatment on the semiconductor wafer W. A gate valve 185 is provided between the transport chamber 170 and the treatment chamber 6 of the heat treatment part 160. The gate valve 185 is opened when a semiconductor wafer W is transferred between the treatment chamber 6 of the heat treatment part 160 and the transport chamber 170. The configuration of the heat treatment part 160 will be described later in detail.

The two cooling parts 130 and 140 are substantially similar in configuration to each other. The cooling parts 130 and 140 include respective metal cooling plates and respective quartz plates (both not shown) placed on the upper surfaces of the cooling plates in the cool chambers 131 and 141 which are housings made of an aluminum alloy. Each of the cooling plates is temperature-controlled at ordinary temperatures (approximately 23° C.) by a Peltier element or by circulation of constant-temperature water. The semiconductor wafer W subjected to the flash heating treatment in the heat treatment part 160 is transported into the cool chamber 131 or the cool chamber 141, and is then placed and cooled on a corresponding one of the quartz plates.

A gate valve 132 is provided in a connector portion between the cool chamber 131 and the transport chamber 170, and a gate valve 142 is provided in a connector portion between the cool chamber 141 and the transport chamber 170. An opening for communication between the cool chamber 131 and the transport chamber 170 is openable and closable by the gate valve 132. An opening for communication between the cool chamber 141 and the transport chamber 170 is openable and closable by the gate valve 142. In other words, the cool chamber 131 and the transport chamber 170 are connected to each other via the gate valve 132, and the cool chamber 141 and the transport chamber 170 are connected to each other via the gate valve 142.

The gate valve 132 is opened when a semiconductor wafer W is transferred between the cool chamber 131 of the cooling part 130 and the transport chamber 170. The gate valve 142 is opened when a semiconductor wafer W is transferred between the cool chamber 141 of the cooling part 140 and the transport chamber 170. When the gate valves 132 and 142 are closed, the interiors of the cool chambers 131 and 141 are enclosed spaces.

The flaw detection part 300 detects the presence or absence of flaws in the back surface of a semiconductor wafer W. One of the main surfaces of the semiconductor wafer W which is patterned and to be treated is a front surface, and the other main surface opposite the front surface is the back surface. The flaw detection part 300 includes an imaging part for imaging the back surface of the semiconductor wafer W, a determination part for determining the presence or absence of flaws by performing predetermined image processing on acquired image data, and the like that are provided in the flaw detection chamber 301 which is a housing made of an aluminum alloy.

A gate valve 302 is provided in a connector portion between the flaw detection chamber 301 and the transport chamber 170. An opening for communication between the flaw detection chamber 301 and the transport chamber 170 is openable and closable by the gate valve 302. In other words, the flaw detection chamber 301 and the transport chamber 170 are connected to each other via the gate valve 302. The gate valve 302 is opened when a semiconductor wafer W is transferred between the flaw detection chamber 301 of the flaw detection part 300 and the transport chamber 170. When the gate valve 302 is closed, the interior of the flaw detection chamber 301 is an enclosed space.

The film thickness measurement part 400 uses, for example, a spectroscopic ellipsometry analysis technique to measure the thickness of a thin film formed on the semiconductor wafer W. The film thickness measurement part 400 includes a table for supporting a semiconductor wafer W, an optical unit, and the like that are provided in the film thickness measurement chamber 401 which is a housing made of an aluminum alloy. The optical unit of a spectroscopic ellipsometer causes light to enter the front surface of the semiconductor wafer W supported by the table, and receives light reflected from the front surface. The optical unit measures the amount of change in polarization of the reflected light for each wavelength to determine the thickness of the thin film formed on the front surface of the semiconductor wafer W, based on the obtained measurement data. It should be noted that the film thickness measurement part 400 is not limited to the aforementioned spectroscopic ellipsometer but may be an optical interference type film thickness measurement device.

A gate valve 402 is provided in a connector portion between the film thickness measurement chamber 401 and the transport chamber 170. An opening for communication between the film thickness measurement chamber 401 and the transport chamber 170 is openable and closable by the gate valve 402. In other words, the film thickness measurement chamber 401 and the transport chamber 170 are connected to each other via the gate valve 402. The gate valve 402 is opened when a semiconductor wafer W is transferred between the film thickness measurement chamber 401 of the film thickness measurement part 400 and the transport chamber 170. When the gate valve 402 is closed, the interior of the film thickness measurement chamber 401 is an enclosed space.

The heat treatment apparatus 100 has what is called a cluster tool structure in which multiple chambers are disposed around the transport chamber 170. The transport robot 150 and the transfer robot 120 constitute a transport mechanism for transporting a semiconductor wafer W from the carriers C to each processing part such as the heat treatment part 160. The transport robot 150 is also a center robot that is positioned in the center of the cooling parts 130 and 140, the flaw detection part 300, the film thickness measurement part 400, and the heat treatment part 160 to transport a semiconductor wafer W to each of these processing parts. The transfer of a semiconductor wafer W between the transport robot 150 and the transfer robot 120 is performed via the alignment part 230 and the warpage measurement part 290. Specifically, the transport robot 150 receives an untreated semiconductor wafer W transferred to the alignment chamber 231 by the transfer robot 120, and the transfer robot 120 receives a treated semiconductor wafer W transferred to the warpage measurement chamber 291 by the transport robot 150. In other words, the alignment chamber 231 serves as an outward path for semiconductor wafers W, and the warpage measurement chamber 291 serves as a return path for semiconductor wafers W. The heat treatment part 160 is a principal part of the heat treatment apparatus 100. The cooling parts 130 and 140, the flaw detection part 300, the film thickness measurement part 400, the alignment part 230, and the warpage measurement part 290 are attendant processing parts that perform processing accompanying the heating treatment of the semiconductor wafer W in the heat treatment part 160 before and after the heating treatment.

Next, the configuration of the heat treatment part 160 will be described. FIG. 2 is a longitudinal sectional view showing the configuration of the heat treatment part 160. The heat treatment part 160 includes the treatment chamber 6 for receiving a semiconductor wafer W therein to perform heating treatment on the semiconductor wafer W, a flash lamp house 5 including the plurality of built-in flash lamps FL, and a halogen lamp house 4 including a plurality of built-in halogen lamps HL. The flash lamp house 5 is provided over the treatment chamber 6, and the halogen lamp house 4 is provided under the treatment chamber 6. The heat treatment part 160 further includes a holder 7 provided inside the treatment chamber 6 and for holding a semiconductor wafer W in a horizontal attitude, and a transfer mechanism 10 provided inside the treatment chamber 6 and for transferring a semiconductor wafer W between the holder 7 and the transport robot 150.

The treatment chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the treatment chamber 6 is a disk-shaped member made of quartz, and serves as a quartz window that transmits flashes of light emitted from the flash lamps FL therethrough into the treatment chamber 6. The lower chamber window 64 forming the floor of the treatment chamber 6 is also a disk-shaped member made of quartz, and serves as a quartz window that transmits light emitted from the halogen lamps HL therethrough into the treatment chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the treatment chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the treatment chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the treatment chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the treatment chamber 6. The transport opening 66 is openable and closable by the gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the treatment chamber 6 is an enclosed space.

The chamber side portion 61 is further provided with a through hole 61a and a through hole 61b both bored therein. The through hole 61a is a cylindrical hole for directing infrared light emitted from an upper surface of a semiconductor wafer W held by a susceptor 74 to be described later therethrough to an infrared sensor 29 of an upper radiation thermometer 25. The through hole 61b is a cylindrical hole for directing infrared light emitted from a lower surface of the semiconductor wafer W therethrough to an infrared sensor 24 of a lower radiation thermometer 20. The through holes 61a and 61b are inclined with respect to a horizontal direction so that the longitudinal axes (axes extending in respective directions in which the through holes 61a and 61b extend through the chamber side portion 61) of the respective through holes 61a and 61b intersect the main surfaces of the semiconductor wafer W held by the susceptor 74. A transparent window 26 made of calcium fluoride material transparent to infrared light in a wavelength range measurable by the upper radiation thermometer 25 is mounted to an end portion of the through hole 61a which faces the heat treatment space 65. A transparent window 21 made of barium fluoride material transparent to infrared light in a wavelength range measurable by the lower radiation thermometer 20 is mounted to an end portion of the through hole 61b which faces the heat treatment space 65.

At least one gas supply opening 81 for supplying a treatment gas therethrough into the heat treatment space 65 is provided in an upper portion of the inner wall of the treatment chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the treatment chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include: inert gases such as nitrogen gas (N₂), argon (Ar), and helium (He); and reactive gases such as hydrogen (H₂), ammonia (NH₃), oxygen (O₂), ozone (O₃), nitrogen monoxide (NO), nitrous oxide (N₂O), and nitrogen dioxide (NO₂) (although nitrogen gas is used in the present preferred embodiment).

At least one gas exhaust opening 86 for exhausting a gas from the heat treatment space 65 is provided in a lower portion of the inner wall of the treatment chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the treatment chamber 6. The gas exhaust pipe 88 is connected to an exhaust mechanism 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the treatment chamber 6, and may be in the form of slits. The treatment gas supply source 85 and the exhaust mechanism 190 may be mechanisms provided in the heat treatment apparatus 100 or be utility systems in a factory in which the heat treatment apparatus 100 is installed.

A gas exhaust pipe 191 for exhausting the gas from the heat treatment space 65 is also connected to a distal end of the transport opening 66. The gas exhaust pipe 191 is connected through a valve 192 to the exhaust mechanism 190. By opening the valve 192, the gas in the treatment chamber 6 is exhausted through the transport opening 66.

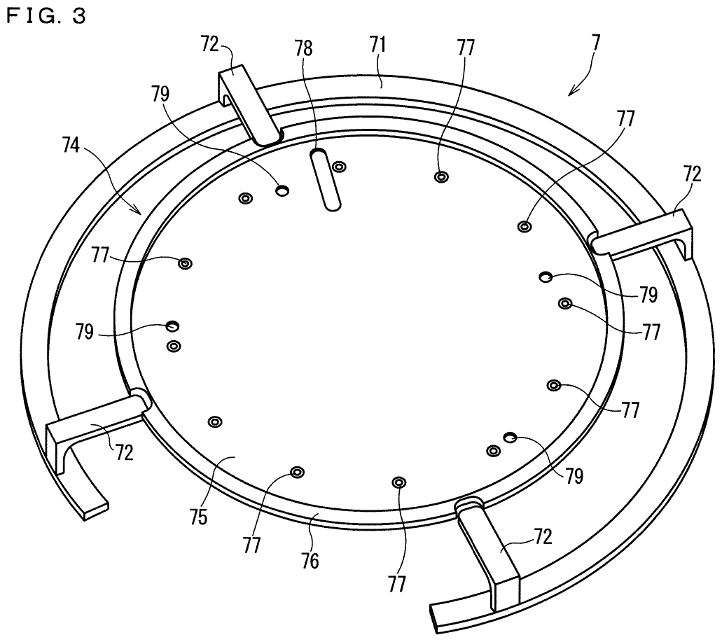

FIG. 3 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the treatment chamber 6 by being placed on the bottom surface of the recessed portion 62 (with reference to FIG. 2). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

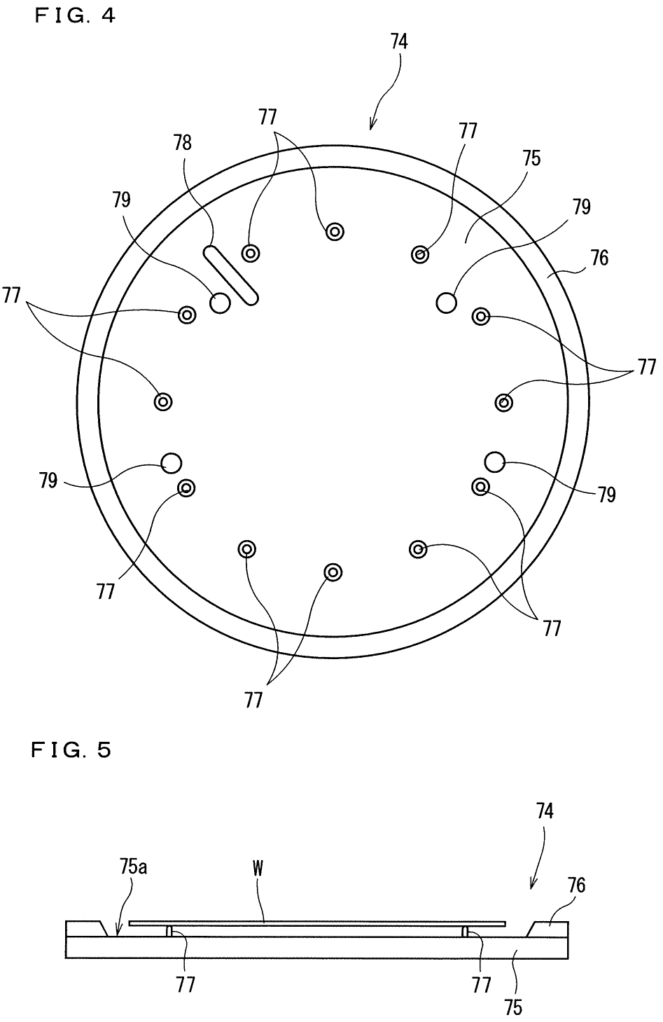

The susceptor 74 is supported by the four coupling portions 72 provided on the base ring 71. FIG. 4 is a plan view of the susceptor 74. FIG. 5 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 3, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the treatment chamber 6, whereby the holder 7 is mounted to the treatment chamber 6. With the holder 7 mounted to the treatment chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the treatment chamber 6 is placed and held in a horizontal attitude on the susceptor 74 of the holder 7 mounted to the treatment chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 3 and 4, an opening 78 is provided in the holding plate 75 of the susceptor 74 so as to extend vertically through the holding plate 75 of the susceptor 74. The opening 78 is provided for the lower radiation thermometer 20 to receive radiation (infrared light) emitted from the lower surface of the semiconductor wafer W. Specifically, the lower radiation thermometer 20 receives the radiation emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

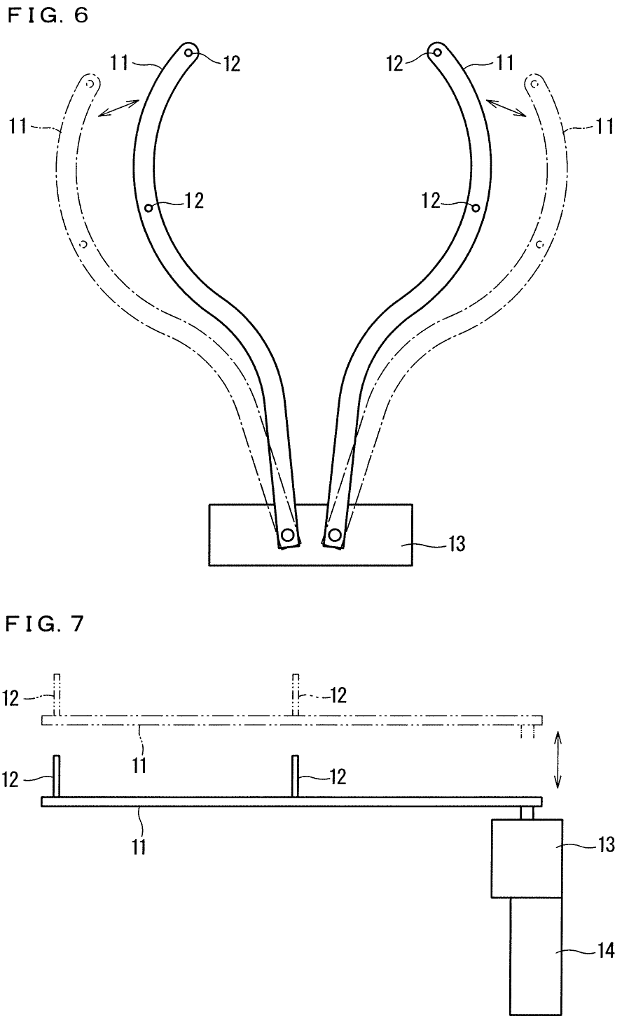

FIG. 6 is a plan view of the transfer mechanism 10. FIG. 7 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 are pivotable by a horizontal movement mechanism 13. The horizontal movement mechanism 13 moves the pair of transfer arms 11 horizontally between a transfer operation position (a position indicated by solid lines in FIG. 6) in which a semiconductor wafer W is transferred to and from the holder 7 and a retracted position (a position indicated by dash-double-dot lines in FIG. 6) in which the transfer arms 11 do not overlap the semiconductor wafer W held by the holder 7 as seen in plan view. The transfer operation position is under the susceptor 74, and the retracted position is outside the susceptor 74. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 3 and 4) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the treatment chamber 6.

As shown in FIG. 2, the treatment chamber 6 is provided with the two radiation thermometers (in the present preferred embodiment, pyrometers): the upper radiation thermometer 25 and the lower radiation thermometer 20. The upper radiation thermometer 25 is provided obliquely above the semiconductor wafer W held by the susceptor 74, and receives the infrared radiation emitted from the upper surface of the semiconductor wafer W to measure the temperature of the upper surface of the semiconductor wafer W. The infrared sensor 29 of the upper radiation thermometer 25 includes an optical element made of InSb (indium antimonide) so as to be able to respond to rapid changes in temperature of the upper surface of the semiconductor wafer W at the moment of flash irradiation. On the other hand, the lower radiation thermometer 20 is provided obliquely below the semiconductor wafer W held by the susceptor 74, and receives the infrared radiation emitted from the lower surface of the semiconductor wafer W to measure the temperature of the lower surface of the semiconductor wafer W.

The flash lamp house 5 provided over the treatment chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash lamp house 5 further includes a lamp light radiation window 53 mounted to the bottom of the enclosure 51. The lamp light radiation window 53 forming the floor of the flash lamp house 5 is a plate-like quartz window made of quartz. The flash lamp house 5 is provided over the treatment chamber 6, whereby the lamp light radiation window 53 is opposed to the upper chamber window 63. The flash lamps FL direct flashes of light from over the treatment chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen lamp house 4 provided under the treatment chamber 6 includes an enclosure 41 incorporating the multiple (in the present preferred embodiment, 40) halogen lamps HL. The halogen lamps HL direct light from under the treatment chamber 6 through the lower chamber window 64 toward the heat treatment space 65.

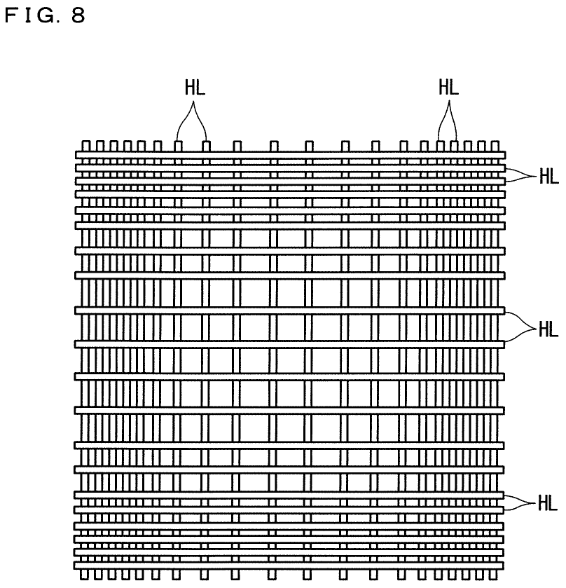

FIG. 8 is a plan view showing an arrangement of the multiple halogen lamps HL. In the present preferred embodiment, 20 halogen lamps HL are arranged in each of two tiers, i.e. upper and lower tiers. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 8, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen lamps HL.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the halogen lamps HL arranged in the upper tier and the longitudinal direction of the halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen lamp house 4 under the halogen lamps HL arranged in two tiers (FIG. 2). The reflector 43 reflects the light emitted from the halogen lamps HL toward the heat treatment space 65.

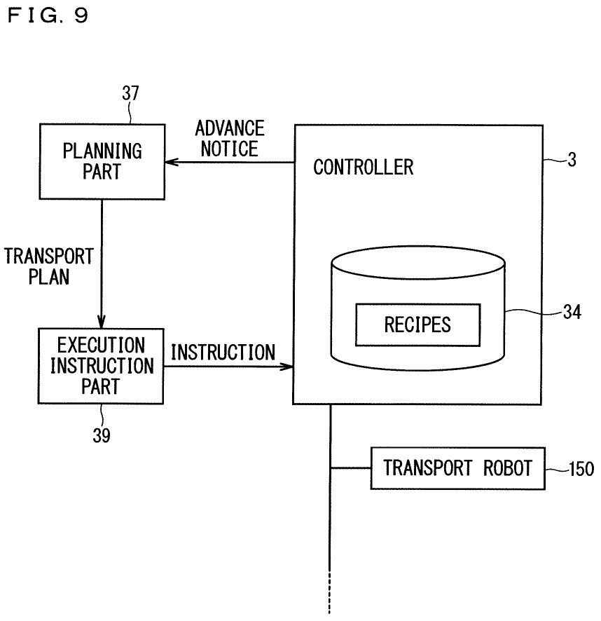

FIG. 9 is a block diagram showing a configuration of the controller 3, the planning part 37, and the execution instruction part 39. The controller 3, the planning part 37, and the execution instruction part 39 are similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part 34 (e.g., a magnetic disk or an SSD) for storing control software, data and the like thereon. The planning part 37 and the execution instruction part 39 are similar in configuration to the controller 3. In FIG. 1, the controller 3, the planning part 37, and the execution instruction part 39 are shown in the indexer part 110. The present invention, however, is not limited to this. The controller 3, the planning part 37, and the execution instruction part 39 may be disposed in any position in the heat treatment apparatus 100.

The controller 3 controls various mechanisms provided in the heat treatment apparatus 100. Specifically, the various mechanisms, such as the transport robot 150, provided in the heat treatment apparatus 100 are electrically connected to the controller 3, and the controller 3 controls the operations of these various mechanisms to cause processes in the heat treatment apparatus 100 to proceed.

The planning part 37 creates a transport plan (transport schedule) for semiconductor wafers W in the heat treatment apparatus 100, based on previously registered processing time in the treatment chamber 6 of the heat treatment part 160 and in the multiple attendant processing parts (the cooling parts 130 and 140, the flaw detection part 300, the film thickness measurement part 400, the alignment part 230, and the warpage measurement part 290). The planning part 37 transfers the created transport plan to the execution instruction part 39.

The execution instruction part 39 instructs the controller 3 to execute the transport and processing of the semiconductor wafers W in accordance with the transport plan created by the planning part 37. In other words, the transport of the semiconductor wafers W is executed in accordance with the previously created transport plan in the heat treatment apparatus 100 of the present preferred embodiment.

The heat treatment part 160 further includes, in addition to the aforementioned components, various cooling structures to prevent an excessive temperature rise in the halogen lamp house 4, the flash lamp house 5, and the treatment chamber 6 because of the heat energy generated from the halogen lamps HL and the flash lamps FL during the heat treatment of a semiconductor wafer W. As an example, a water cooling tube (not shown) is provided in the walls of the treatment chamber 6. Also, the halogen lamp house 4 and the flash lamp house 5 have an air cooling structure for forming a gas flow therein to exhaust heat. Air is supplied to a gap between the upper chamber window 63 and the lamp light radiation window 53 to cool down the flash lamp house 5 and the upper chamber window 63.

Nitrogen is supplied from an inert gas supply mechanism not shown to the cool chambers 131 and 141, the flaw detection chamber 301, the film thickness measurement chamber 401, the alignment chamber 231, the warpage measurement chamber 291, and the transport chamber 170. At the same time, an exhaust mechanism exhausts gas from the cool chambers 131 and 141, the flaw detection chamber 301, the film thickness measurement chamber 401, the alignment chamber 231, the warpage measurement chamber 291, and the transport chamber 170. This maintains a low oxygen concentration atmosphere in each of the chambers.

Next, a processing operation in the heat treatment apparatus 100 according to the present invention will be described. First, a typical processing operation for a single semiconductor wafer (product wafer) W that becomes a product will be described. A procedure for processing of the semiconductor wafer W which will be described below proceeds under the control of the controller 3 over the operating mechanisms of the heat treatment apparatus 100.

First, while being stored in a carrier C, untreated semiconductor wafers W of silicon are placed on any one of the three load ports 111 of the indexer part 110. The transfer robot 120 takes an untreated semiconductor wafer W out of the carrier C. The transfer robot 120 transports the semiconductor wafer W taken out of the carrier C into the alignment chamber 231 of the alignment part 230. The alignment part 230 rotates the semiconductor wafer W transported into the alignment chamber 231 in a horizontal plane about a vertical axis passing through the central portion of the semiconductor wafer W, and optically detects a notch or the like to thereby adjust the orientation of the semiconductor wafer W.

Next, the transport robot 150 transports the semiconductor wafer W from the alignment chamber 231 to the transport chamber 170. Then, the transport robot 150 transports the semiconductor wafer W into the flaw detection chamber 301 of the flaw detection part 300. In the flaw detection part 300, the back surface of the semiconductor wafer W transported into the flaw detection chamber 301 is imaged, and the presence or absence of flaws is detected by analyzing the obtained image data. A semiconductor wafer W in which any flaw is detected may be returned to the carrier C because there is a danger that the semiconductor wafer W is cracked when irradiated with a flash of light in the heat treatment part 160.

Next, the transport robot 150 transports the semiconductor wafer W from the flaw detection chamber 301 into the film thickness measurement chamber 401 of the film thickness measurement part 400. The film thickness measurement part 400 measures the thickness of a thin film formed on the front surface of the semiconductor wafer W transported into the film thickness measurement chamber 401. At this time, the film thickness measurement part 400 measures the film thickness of the semiconductor wafer W prior to the heat treatment in the heat treatment part 160.

After the completion of the film thickness measurement prior to the treatment, the transport robot 150 transports the semiconductor wafer W from the film thickness measurement chamber 401 into the treatment chamber 6 of the heat treatment part 160. In the heat treatment part 160, the heating treatment of the semiconductor wafer W is performed.

Prior to the transport of the semiconductor wafer W into the treatment chamber 6, the valve 84 for supply of gas is opened, and the valves 89 and 192 for exhaust of gas are opened, so that the supply and exhaust of gas into and out of the treatment chamber 6 start. When the valve 84 is opened, nitrogen gas is supplied through the gas supply opening 81 into the heat treatment space 65. When the valve 89 is opened, the gas within the treatment chamber 6 is exhausted through the gas exhaust opening 86. This causes the nitrogen gas supplied from an upper portion of the heat treatment space 65 in the treatment chamber 6 to flow downwardly and then to be exhausted from a lower portion of the heat treatment space 65. The gas within the treatment chamber 6 is exhausted also through the transport opening 66 by opening the valve 192. Further, the exhaust mechanism not shown exhausts an atmosphere near the drivers of the transfer mechanism 10.

Subsequently, the gate valve 185 is opened to open the transport opening 66. The transport robot 150 transports the semiconductor wafer W to be treated through the transport opening 66 into the heat treatment space 65 of the treatment chamber 6. The transport robot 150 moves the transport hand 151a (or the transport hand 151b) holding the untreated semiconductor wafer W forward to a position lying immediately over the holder 7, and stops the transport hand 151a (or the transport hand 151b) thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the untreated semiconductor wafer W is placed on the lift pins 12, the transport robot 150 causes the transport hand 151a to move out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface to be treated is the upper surface. A predetermined distance is defined between the back surface of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is transported into the treatment chamber 6 and held by the susceptor 74, the 40 halogen lamps HL turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured by the lower radiation thermometer 20 when the halogen lamps HL perform the preheating. Specifically, the lower radiation thermometer 20 receives infrared radiation emitted from the lower surface of the semiconductor wafer W held by the susceptor 74 through the opening 78 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the lower radiation thermometer 20.

After the temperature of the semiconductor wafer W reaches a preheating temperature T1, the controller 3 maintains the temperature of the semiconductor wafer W at the preheating temperature T1 for a short time. Specifically, at the point in time when the temperature of the semiconductor wafer W measured by the lower radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen lamp house 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL irradiate the front surface of the semiconductor wafer W with a flash of light at the point in time when a predetermined time period has elapsed since the temperature of the semiconductor wafer W reached the preheating temperature T1. At this time, part of the flash of light emitted from the flash lamps FL travels directly toward the interior of the treatment chamber 6. The remainder of the flash of light is reflected once from the reflector 52, and then travels toward the interior of the treatment chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2, and thereafter decreases rapidly.

After a predetermined time period has elapsed since the completion of the flash heating treatment, the halogen lamps HL turn off. This causes the temperature of the semiconductor wafer W to decrease rapidly from the preheating temperature T1. The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport hand 151b (or the transport hand 151a) of the transport robot 150 transports the treated semiconductor wafer W placed on the lift pins 12 to the outside. Specifically, the transport robot 150 moves the transport hand 151b forward to a position lying immediately under the semiconductor wafer W thrust upwardly by the lift pins 12, and stops the transport hand 151b thereat. Then, the pair of transfer arms 11 moves downwardly, whereby the semiconductor wafer W subjected to the flash heating is transferred to and placed on the transport hand 151b. Thereafter, the transport robot 150 causes the transport hand 151b to move out of the treatment chamber 6, thereby transporting the heat-treated semiconductor wafer W to the transport chamber 170.

Next, the transport robot 150 transports the heat-treated semiconductor wafer W into the cool chamber 131 of the cooling part 130. The cooling part 130 cools the semiconductor wafer W at a relatively high temperature immediately after the heat treatment to near ordinary temperatures. The process of cooling the semiconductor wafer W may be performed in the cool chamber 141 of the cooling part 140.

After the completion of the cooling process, the transport robot 150 transports the cooled semiconductor wafer W from the cool chamber 131 into the film thickness measurement chamber 401. The film thickness measurement part 400 measures the thickness of a thin film formed on the front surface of the semiconductor wafer W transported into the film thickness measurement chamber 401. At this time, the film thickness measurement part 400 measures the film thickness of the semiconductor wafer W subjected to the heat treatment in the heat treatment part 160. In the case where the film deposition process is performed by the flash heating treatment in the heat treatment part 160, the thickness of the deposited thin film is calculated by subtracting the film thickness measured prior to the treatment from the film thickness measured after the treatment.

After the completion of the film thickness measurement after the treatment, the transport robot 150 transports the semiconductor wafer W from the film thickness measurement chamber 401 to the transport chamber 170. Then, the transport robot 150 transports the semiconductor wafer W into the warpage measurement chamber 291 of the warpage measurement part 290. The warpage measurement part 290 measures the warpage occurring in the semiconductor wafer W subjected to the heating treatment.

After the completion of the wafer warpage measurement, the transfer robot 120 takes the semiconductor wafer W out of the warpage measurement chamber 291. Then, the transfer robot 120 stores the semiconductor wafer W taken out of the warpage measurement chamber 291 into the original carrier C. In this manner, the heat treatment of the single semiconductor wafer W is completed.

As already mentioned, it is desirable that the transport robot 150, for example, uses the transport hand 151b that is one of the transport hands to transport a preceding semiconductor wafer W subjected to the heating treatment from the treatment chamber 6 and uses the transport hand 151a that is the other transport hand to transport a succeeding untreated semiconductor wafer W into the treatment chamber 6, thereby performing wafer exchange. However, the wafer exchange cannot be performed unless the succeeding semiconductor wafer W has reached the transport robot 150 when the treatment of the preceding semiconductor wafer W is completed in the treatment chamber 6. In particular, the heat treatment apparatus 100 of the present preferred embodiment has the cluster tool structure in which the multiple chambers are disposed around the transport chamber 170, and the aforementioned situation is likely to occur when the transport robot 150 performs the transport operation in response to a request (a carry-out or carry-in request) from a transport destination part (what is called an event-driven scheme). To prevent such a situation, the transport control of the semiconductor wafers W is performed in a manner to be described below in the first preferred embodiment.

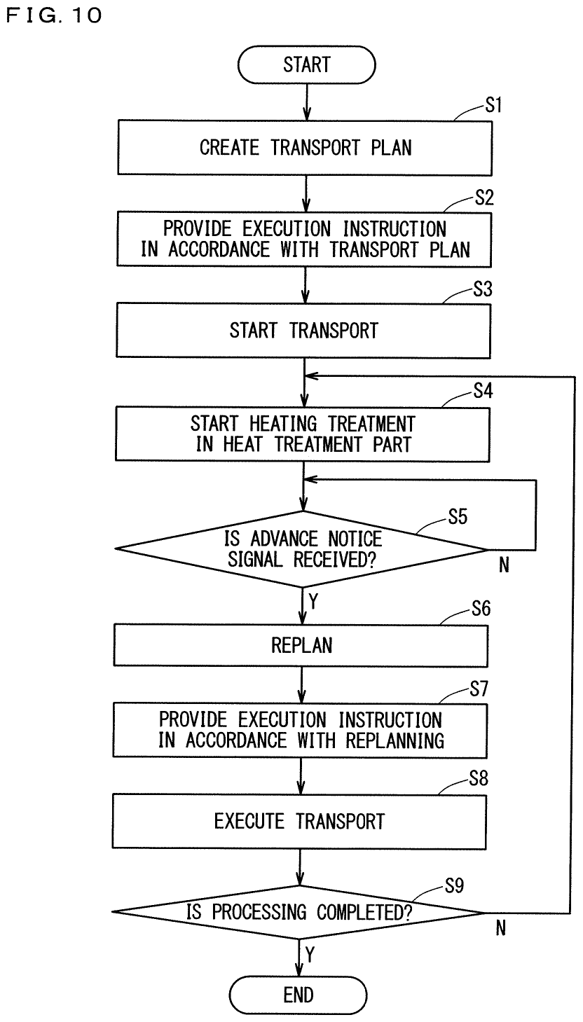

FIG. 10 is a flow diagram showing a procedure for the transport control of semiconductor wafers W in the first preferred embodiment. First, the planning part 37 creates a transport plan for a plurality of semiconductor wafers W constituting a single lot (Step S1). A single lot includes, for example, 25 semiconductor wafers W, which are typically stored in a single carrier C. The time at which the planning part 37 creates the transport plan may be, for example, when the carrier C containing a lot to be processed is placed on one of the load ports 111 and a recipe is assigned to the plurality of semiconductor wafers W included in the lot. The recipe refers to a specification of the heat treatment procedure and heat treatment conditions for semiconductor wafers W. Various types of recipes are previously created and stored, for example, in the storage part 34 of the controller 3 (FIG. 9).

The planning part 37 creates the transport plan for a set of semiconductor wafers W included in a lot, based on previously registered processing time in the treatment chamber 6 of the heat treatment part 160 and in the attendant processing parts (the cooling parts 130 and 140, the flaw detection part 300, the film thickness measurement part 400, the alignment part 230, and the warpage measurement part 290). The planning part 37 creates the transport plan, based on the processing time written in the recipe assigned to these semiconductor wafers W, for example. The processing time in each of the treatment chamber 6 and the attendant processing parts is also specified in the recipe.

The transport plan created by the planning part 37 is transferred to the execution instruction part 39. The execution instruction part 39 provides an execution instruction to the controller 3 so as to execute the transport and processing of the semiconductor wafers W in accordance with the transport plan created by the planning part 37 (Step S2). Based on the execution instruction from the execution instruction part 39, the controller 3 starts the transport of the semiconductor wafers W in accordance with the transport plan (Step S3). The procedure for the transport of a single semiconductor wafer W is as described above.

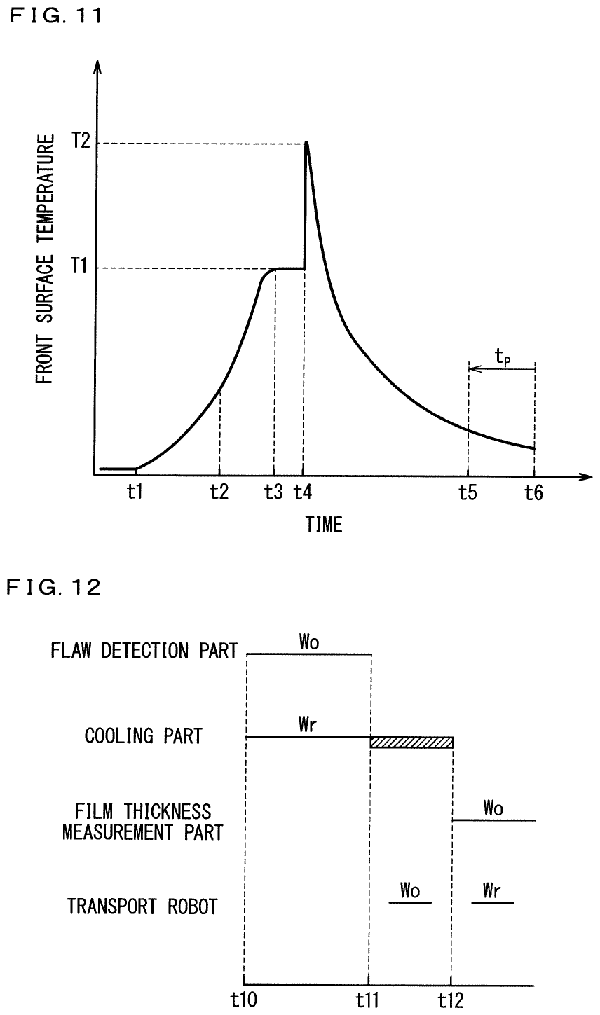

The first semiconductor wafer W in the lot is transported into the treatment chamber 6 of the heat treatment part 160, and the heating treatment of the first semiconductor wafer W is started (Step S4). The procedure for the heating treatment of the semiconductor wafer W in the heat treatment part 160 is also as described above. FIG. 11 is a graph showing changes in temperature of the semiconductor wafer W during the heating treatment in the heat treatment part 160. In a strict sense, FIG. 11 shows changes in front surface temperature of the semiconductor wafer W.

At time t1, the halogen lamps HL turn on to start the preheating. At time t3, the temperature of the semiconductor wafer W reaches the preheating temperature T1. Thereafter, at time t4, a flash of light is emitted from the flash lamps FL, so that the front surface temperature of the semiconductor wafer W momentarily increases to the treatment temperature T2. Thereafter, the halogen lamps HL also turn off, so that the temperature of the semiconductor wafer W decreases rapidly. At time t6, the heating treatment of the semiconductor wafer W is completed. Since the inside of the treatment chamber 6 is heated by the light irradiation from the halogen lamps HL and the flash lamps FL, the temperature of the treatment chamber 6 is accordingly high even at the time t6 when the heating treatment of the semiconductor wafer W is completed.

A time period from the time t1 when the preheating starts to time t2, i.e. an early stage of the preheating, is a non-time-management phase in which no time management is performed. The time period from the time t1 to the time t2 is a time period during which the controller 3 effects the feedback control of the output from the halogen lamps HL, based on the temperature value of the semiconductor wafer W measured by the lower radiation thermometer 20. During this time period, the measurement value is not stabilized due to the influence of disturbance on the lower radiation thermometer 20. This makes the output from the halogen lamps HL unstable to cause the time period to fluctuate. That is, the time period from the time t1 to the time t2 is not constant.

After the time t2, on the other hand, a time management phase in which management is performed by time is entered. In this time management phase, the timing of light emission from the flash lamps FL, for example, is managed by time. A time period from the time t2 to the time t4 at which the flash irradiation is performed and a time period from the time t2 to the time t6 at which the heating treatment of the semiconductor wafer W is completed are constant (for example, 40 seconds).

After the time t2, the controller 3 is hence able to identify the time t6 when the heating treatment of the semiconductor wafer W is completed. Then, the controller 3 transmits an advance notice signal to the planning part 37 at time t5 that is a certain amount of time tp before the time t6 when the heating treatment of the semiconductor wafer W is completed in the treatment chamber 6.

The planning part 37 waits until receiving the advance notice signal from the controller 3 (Step S5). It should be noted that the heating treatment of the semiconductor wafer W is still proceeding under the control of the controller 3 while the planning part 37 is waiting. Then, the planning part 37 executes the replanning of the transport at the time t5 when the planning part 37 receives the advance notice signal from the controller 3 (Step S6). The planning part 37 executes the replanning of the transport so that the transport robot 150 is able to transport the semiconductor wafer W from the treatment chamber 6 at the time t6 when the heating treatment of the semiconductor wafer W is completed in the treatment chamber 6. Specifically the planning part 37 executes the replanning so that the next step of the transport operation being performed by the transport robot 150 at the time (the time t5) when the planning part 37 receives the advance notice signal from the controller 3 is the transport of the semiconductor wafer W from the treatment chamber 6.

For example, it is assumed that, while the heating treatment of a preceding semiconductor wafer W1 (referred to hereinafter as a “preceding wafer W1”) is being performed in the treatment chamber 6, the film thickness measurement of a succeeding semiconductor wafer W2 (referred to hereinafter as a “succeeding wafer W2”) is completed in the film thickness measurement part 400. The transport robot 150 performs the operation of transporting the succeeding wafer W2 from the film thickness measurement chamber 401 of the film thickness measurement part 400 in accordance with the initial transport plan. If the controller 3 transmits the advance notice signal during the execution of the transport operation, the transport operation being performed by the transport robot 150 at the time that the planning part 37 receives the advance notice signal is the operation of transporting the succeeding wafer W2 from the film thickness measurement part 400. Even if the initial transport plan is designed, for example, so that the transport operation from the film thickness measurement part 400 is followed by the transport operation from the cooling part 130, the planning part 37 replans the transport so that the transport operation from the film thickness measurement part 400 is followed by the operation of transporting the preceding wafer W1 from the treatment chamber 6 by placing the transport operation from the cooling part 130 in a waiting state.

The replanning of the transport created by the planning part 37 is transferred to the execution instruction part 39, and the execution instruction part 39 provides an execution instruction to the controller 3 in accordance with the replanning (Step S7). Based on the execution instruction from the execution instruction part 39, the controller 3 causes the transport robot 150 to transport the semiconductor wafers W in accordance with the replanning (Step S8). In the aforementioned example of the replanning, the transport robot 150 performs the operations so that the operation of transporting the succeeding wafer W2 from the film thickness measurement part 400 is followed by the operation of transporting the preceding wafer W1 from the treatment chamber 6.

The certain amount of time tp which is the time difference between the time t6 when the heating treatment of the semiconductor wafer W is completed in the treatment chamber 6 and the time t5 when the advance notice signal is transmitted is defined as the sum of the time required for the transport robot 150 to perform the pivotal movement and the time required for the transport robot 150 to transport the semiconductor wafer W to or from an attendant processing part other than the treatment chamber 6. For example, if the time required for the transport robot 150 to perform the pivotal movement is 3 seconds and the time required for the transport robot 150 to transport the semiconductor wafer W to or from any one of the attendant processing parts is 6 seconds, the certain amount of time tp is 9 seconds. The certain amount of time tp is stored as an apparatus parameter, for example, in the storage part 34 of the controller 3.

The controller 3 transmits the advance notice signal at the time t5 that is the certain amount of time tp before the time t6 when the heating treatment of the preceding wafer W1 is completed in the treatment chamber 6, so that the planning part 37 executes the replanning. This allows the transport robot 150 to complete the operation of transporting the succeeding wafer W2 from the film thickness measurement part 400 at the time t6 with reliability and to transport the semiconductor wafers W to and from the treatment chamber 6. That is, the transport robot 150 is able to transport the preceding wafer W1 from the treatment chamber 6 with reliability at the time t6 when the heating treatment of the preceding wafer W1 is completed in the treatment chamber 6. At the time t6, the transport robot 150 is also able to perform the wafer exchange by transporting the preceding wafer W1 subjected to the heating treatment from the treatment chamber 6 and transporting the succeeding wafer W2 into the treatment chamber 6.

Then, if the processing for all of the semiconductor wafers W in the lot has not yet been completed, the procedure returns from Step S9 to Step S4. For the second and subsequent semiconductor wafers W, the planning part 37 executes the replanning of the transport when the advance notice signal is transmitted, and each of the semiconductor wafers W is transported in accordance with the replanning. In other words, Steps S4 to S9 are repeatedly executed until the processing for all of the semiconductor wafers W in the lot is completed.

If the planning part 37 does not receive the advance notice signal at a previously assumed time, the transport robot 150 does not transport the preceding wafer W1 from the treatment chamber 6, but is in the waiting state while holding the succeeding wafer W2. Such a case may be a case in which a longer time period than planned is required for the preheating of the preceding wafer W1 by the halogen lamps HL. Even if the transport robot 150 is in the waiting state while holding the succeeding wafer W2, the transport of the preceding wafer W1 from the treatment chamber 6 is executable at the time that the heating treatment of the preceding wafer W1 is completed. Also, there is no problem even if an untreated succeeding wafer W2 not yet subjected to the heating treatment is placed in the waiting state.

In the first preferred embodiment, the controller 3 transmits the advance notice signal to the planning part 37 at the time t5 that is the certain amount of time tp before the time t6 when the heating treatment of the semiconductor wafer W is completed in the treatment chamber 6. The certain amount of time tp is the sum of the time required for the transport robot 150 to perform the pivotal movement and the time required for the transport robot 150 to transport the semiconductor wafer W to or from an attendant processing part other than the treatment chamber 6. Then, the planning part 37 executes the replanning of the transport so that the next step of the transport operation being performed by the transport robot 150 at the time (the time t5) when the planning part 37 receives the advance notice signal is the transport of the semiconductor wafer W from the treatment chamber 6.

The planning part 37 executes the replanning of the transport each time the heating treatment of a semiconductor wafer W is performed. Thus, the transport of the semiconductor wafer W is adjusted automatically and rapidly.

The procedure as in the first preferred embodiment allows the transport robot 150 to transport the semiconductor wafer W from the treatment chamber 6 with reliability at the time that the heating treatment of the semiconductor wafer W is completed. As a result, the semiconductor wafer W subjected to the heating treatment is transported from the treatment chamber 6 without waiting for a longer time period than necessary in the treatment chamber 6 which is high in temperature. This prevents the application of an excessive amount of heat to the semiconductor wafer W from affecting the treatment results.

### Second Preferred Embodiment

Next, a second preferred embodiment of the present invention will be described. The configurations of the heat treatment apparatus 100 and the heat treatment part 160 in the second preferred embodiment are the same as those in the first preferred embodiment. The procedure for the heating treatment of a single semiconductor wafer W in the second preferred embodiment is the same as that in the first preferred embodiment. The procedure for the transport control of semiconductor wafers W in the second preferred embodiment is substantially the same as that in the first preferred embodiment (FIG. 10).

In the second preferred embodiment, when creating a transport plan for a plurality of semiconductor wafers W (Step S1 in FIG. 10), the planning part 37 creates a plan that places priority on a semiconductor wafer W in an outward path. The semiconductor wafer W in the outward path refers to a semiconductor wafer W not yet subjected to the heating treatment by the heat treatment part 160, that is, a semiconductor wafer W being transported from the load ports 111 toward the treatment chamber 6. On the other hand, a semiconductor wafer W in a return path refers to a semiconductor wafer W subjected to the heating treatment by the heat treatment part 160, that is, a semiconductor wafer W being transported from the treatment chamber 6 toward the load ports 111.

FIG. 12 is a schematic illustration of priority transport of a semiconductor wafer W in the outward path. At certain time t10, a semiconductor wafer Wo in the outward path which is not yet subjected to the heating treatment (referred to hereinafter as an “outward wafer Wo”) is received in the flaw detection chamber 301 of the flaw detection part 300, and the presence or absence of a flaw in the outward wafer Wo is being detected. At the same time, a semiconductor wafer Wr in the return path which is subjected to the heating treatment in the heat treatment part 160 (referred to hereinafter as a “return wafer Wr”) is transported to and being cooled in the cool chamber 131 of the cooling part 130. Then, at time t11, the flaw detection process of the outward wafer Wo in the flaw detection part 300 is completed, and the cooling process of the return wafer Wr in the cooling part 130 has been also completed. In other words, both the transport of the outward wafer Wo from the flaw detection part 300 and the transport of the return wafer Wr from the cooling part 130 are executable at the time t11.

Both the transport of the outward wafer Wo from the flaw detection part 300 and the transport of the return wafer Wr from the cooling part 130 are performed by the transport robot 150. However, the transport robot 150 cannot simultaneously perform the transport operations to two attendant processing parts. Thus, the transport of the outward wafer Wo and the transport of the return wafer Wr by the transport robot 150 compete with each other at the time t11.

In the second preferred embodiment, the planning part 37 creates a transport plan so that priority is placed on the transport of the semiconductor wafer W in the outward path which is not yet subjected to the heating treatment when the transport of the outward wafer Wo and the transport of the return wafer Wr by the transport robot 150 compete with each other. In other words, at the time t11, the transport robot 150 transports the outward wafer Wo from the flaw detection part 300 before transporting the return wafer Wr.

Thereafter, at time t12, the transport robot 150 transports the outward wafer Wo to the film thickness measurement part 400 that is the next step. At this time, the transport of the return wafer Wr from the cooling part 130 becomes executable, so that the transport robot 150 transports the return wafer Wr from the cooling part 130. In short, as a result of placing priority on the transport of the outward wafer Wo, the return wafer Wr waits in the cooling part 130 during a time interval between the time t11 after the completion of the cooling process and the time t12 (a shaded portion in FIG. 12).

The planning part 37 creates the transport plan that places priority on the transport of the semiconductor wafer Wo in the outward path as described above. The created transport plan is transferred to the execution instruction part 39. The execution instruction part 39 provides the execution instruction to the controller 3 in accordance with the transport plan. Based on the execution instruction from the execution instruction part 39, the controller 3 causes the transport robot 150 to transport the semiconductor wafers W in accordance with the transport plan.

In the second preferred embodiment, the planning part 37 creates the transport plan so that priority is placed on the transport of the semiconductor wafer W not yet subjected to the heating treatment when the transport of the semiconductor wafer W not yet subjected to the heating treatment and the transport of the semiconductor wafer W subjected to the heating treatment by the transport robot 150 compete with each other. This suppresses the prolonged time required to transport the semiconductor wafer W in the outward path from the load ports 111 to the transport robot 150. Thus, when the heating treatment of the preceding semiconductor wafer W is completed in the treatment chamber 6, the succeeding semiconductor wafer W will always reach the transport robot 150. As a result, the wafer exchange of the preceding and succeeding semiconductor wafers W in the treatment chamber 6 is performed with reliability. Any semiconductor wafer W is always present in the treatment chamber 6, and the temperature in the treatment chamber 6 is maintained at a stable temperature without decreasing. Thus, the temperature in the treatment chamber 6 is constant for all succeeding semiconductor wafers W constituting a lot, so that the treatment results of the succeeding semiconductor wafers W are uniform. There are cases in which the transport of the semiconductor wafer W in the return path takes a long time as a result of placing priority on the transport of the semiconductor wafer W in the outward path. However, in the example of FIG. 12, for example, the semiconductor wafer W in the return path will wait a longer time period than planned in the cooling part 130, but the prolonged cooling time, if any, does not affect the treatment result of the semiconductor wafer W in the return path.

### Modifications

While the preferred embodiments according to the present invention have been described hereinabove, various modifications of the present invention in addition to those described above may be made without departing from the scope and spirit of the invention. For example, the first and second preferred embodiments may be implemented together. Specifically, the planning part 37 may create a plan that places priority on the transport of the semiconductor wafer W in the outward path, and execute the replanning of transport when receiving the advance notice signal.

In the aforementioned preferred embodiments, three computers, i.e. the controller 3, the planning part 37, and the execution instruction part 39, are individually provided in the heat treatment apparatus 100. The present invention, however, is not limited to this. For example, the planning part 37 and the execution instruction part 39 may be functionally implemented by software in the controller 3. Alternatively, the planning part 37 and the execution instruction part 39 may be provided in a host computer that manages a plurality of heat treatment apparatuses 100.

In the aforementioned preferred embodiments, the certain amount of time tp is defined as the sum of the time required for the transport robot 150 to perform the pivotal movement and the time required for the transport robot 150 to transport the semiconductor wafer W to or from an attendant processing part. The present invention, however, is not limited to this. The certain amount of time tp is required only to be not less than the time required for the transport robot 150 to be ready to transport the treated semiconductor wafer W from the treatment chamber 6 when the heating treatment of the semiconductor wafer W is completed in the treatment chamber 6.

The film thickness measurement is performed before and after the heat treatment in the heat treatment part 160 in the aforementioned preferred embodiments, but this is not essential. The film thickness measurement before the heat treatment need not be performed. In this case, the semiconductor wafer W subjected to the detection of the presence or absence of a flaw in the flaw detection part 300 is transported directly to the treatment chamber 6 of the heat treatment part 160.

Although the 30 flash lamps FL are provided in the flash lamp house 5 in the aforementioned preferred embodiments, the present invention is not limited to this. Any number of flash lamps FL may be provided. The flash lamps FL are not limited to the xenon flash lamps, but may be krypton flash lamps. Also, the number of halogen lamps HL provided in the halogen lamp house 4 is not limited to 40. Any number of halogen lamps HL may be provided.

In the aforementioned preferred embodiments, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus for heating a substrate by irradiating the substrate with light, comprising:
a treatment chamber for receiving a substrate therein;
a lamp for irradiating the substrate received in said treatment chamber with light;
a plurality of attendant processing parts for performing processes before and after heating treatment in said treatment chamber;
a transport robot for transporting the substrate to and from said treatment chamber and said attendant processing parts;
a controller for controlling a mechanism provided in said heat treatment apparatus;
a planning part for creating a transport plan based on previously registered processing time in said treatment chamber and in said attendant processing parts; and
an execution instruction part for instructing said controller to execute the transport and processes of substrates in accordance with said transport plan created by said planning part.

2. The heat treatment apparatus according to claim 1,
wherein said controller transmits an advance notice signal to said planning part at a time that is a certain amount of time before the time at which the heating treatment is completed in said treatment chamber; and
wherein, when receiving said advance notice signal from said controller, said planning part executes replanning of transport so that said transport robot is able to transport the substrate from said treatment chamber at the time of completion of the heating treatment in said treatment chamber.

3. The heat treatment apparatus according to claim 2,
wherein said planning part executes the replanning so that the transport operation being performed by said transport robot when receiving said advance notice signal is followed by the transport of the substrate from said treatment chamber.

4. The heat treatment apparatus according to claim 2,
wherein said certain amount of time is the sum of the time required for said transport robot to perform a pivotal movement and the time required for said transport robot to transport the substrate to or from any one of said attendant processing parts.

5. The heat treatment apparatus according to claim 1,
wherein said planning part creates a transport plan so that priority is placed on the transport of a substrate not yet subjected to the heating treatment when the transport of the substrate not yet subjected to the heating treatment and the transport of a substrate subjected to the heating treatment by said transport robot compete with each other.

6. The heat treatment apparatus according to claim 1,
wherein said attendant processing parts include a cooling part, a flaw detection part, and a film thickness measurement part.

7. A method of heating a substrate received in a treatment chamber by irradiating the substrate with light from a lamp, said method comprising the steps of:
(a) transporting substrates to and from said treatment chamber and a plurality of attendant processing parts for performing processes before and after heating treatment in said treatment chamber by means of a transport robot under the control of a controller;
(b) creating a transport plan by means of a planning part, based on previously registered processing time in said treatment chamber and in said attendant processing parts; and
(c) instructing said controller to execute the transport and processes of the substrates in accordance with said transport plan created in said step (b).

8. The method according to claim 7,
wherein said controller transmits an advance notice signal to said planning part at a time that is a certain amount of time before the time at which the heating treatment is completed in said treatment chamber; and
wherein, when receiving said advance notice signal from said controller, said planning part executes replanning of transport so that said transport robot is able to transport a substrate from said treatment chamber at the time of completion of the heating treatment in said treatment chamber.

9. The method according to claim 8,
wherein said planning part executes the replanning so that the transport operation being performed by said transport robot when receiving said advance notice signal is followed by the transport of the substrate from said treatment chamber.

10. The method according to claim 8,
wherein said certain amount of time is the sum of the time required for said transport robot to perform a pivotal movement and the time required for said transport robot to transport the substrate to or from any one of said attendant processing parts.

11. The method according to claim 7,
wherein a transport plan is created in said step (b) so that priority is placed on the transport of a substrate not yet subjected to the heating treatment when the transport of the substrate not yet subjected to the heating treatment and the transport of a substrate subjected to the heating treatment by said transport robot compete with each other.

12. The method according to claim 7,
wherein said attendant processing parts include a cooling part, a flaw detection part, and a film thickness measurement part.
